(19) United States
(12) Patent Application Publication
(10) Pub. No.: US 2007/0152680 A1
(43) Pub. Date: Jul. 5, 2007

(54) DUTY DETECTION CIRCUIT, DLL CIRCUIT AND SEMICONDUCTOR DEVICE HAVING SAME

(75) Inventors: Hiroki FUJISAWA, Tokyo (JP); Ryuji TAKISHITA, Kodaira-shi (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/553,908

(22) Filed: Oct. 27, 2006

(30) Foreign Application Priority Data
Oct. 28, 2005 (JP) 2005-313714

(51) Int. Cl. G01R 27/28

(52) U.S. Cl. 324/617

(57) ABSTRACT

Accurate duty detection is enabled by performing duty detection once every two cycles while delaying detection of one clock logic level by a half cycle, and presetting the potential of a common contact to an initial set value during the delay time. A DLL circuit employing a divide-by-two scheme is provided with separate duty detection circuits for even-numbered and odd-numbered cycles to detect duties of the respective cycles, respectively. The DLL circuit having this configuration and a semiconductor device having such DLL circuit are capable of accurate timing adjustment to the clock.

This application claims priority to prior application JP 2005-313714, the disclosure of which is incorporated herein by reference.

### BACKGROUND OF THE INVENTION

The present invention relates to a duty detection circuit for detecting deviation in clock duty, and a DLL circuit and semiconductor device having such duty detection circuit.

Electronic systems of late are designed to operate at high speed, and the data transmission rate among semiconductor devices forming such electronic system is also very high. Thus, each of the semiconductor devices is also required to operate at a high data transmission rate, employing a clock synchronization system to synchronize clocks within the semiconductor device. For example, a synchronous dynamic random access memory (hereafter, abbreviated to “SDRAM”) is one of such semiconductor storage devices. The SDRAM has been further evolved as double data rate (DDR), DDR2 and DDR3 SDRAMs in which synchronization is performed at the rising/falling edge of a clock.

In these DDR-SDRAMs, a delay lock loop (DLL) circuit is employed to synchronize the phase of output data to the phase of an external clock. According to the DDR method, however, an input clock is frequency-multiplied or frequency-divided in the semiconductor device in order to perform synchronization at the rising or falling edge of the clock. The rising edge and the falling edge of the multiplied or divided clock are adjusted separately. Therefore, the rising edge and the falling edge have independent timings, which changes the clock duty. The change of the clock duty induces a problem of clock duty deviation. A duty detection circuit and a duty correction circuit are used for correcting this clock duty deviation.

Conventional duty detection circuits however have a problem that the accuracy to detect duty deviation is poor.

FIG. 1 shows a conventional duty detection circuit, and FIG. 2 shows a timing chart thereof.

The duty detection circuit shown in FIG. 1 is a differential amplification circuit, composed of a current source MOS transistor 61, differential input MOS transistors 62 and 63, load MOS transistors 64 and 65, precharge MOS transistors 66, 67, and 68, input control circuits 69 and 72, and a comparator 73 comparing outputs from the differential amplifier.

Operation of the duty detection circuit will be described with reference to the timing chart of FIG. 2.

Prior to duty detection, outputs DUTY_HB and DUTY_LB are precharged to a power source potential by the precharge MOS transistors 66, 67, and 68. Detection start signals LDCSMT/B are activated to start the duty detection. While a clock LCLKOET is at high level, the differential input MOS transistor 62 is kept ON to extract electric charge of the precharged output DUTY_LB to reduce the potential thereof. While an inverted clock LCLKOEB is at high level, the differential input MOS transistor 63 is kept ON to extract the electric charge of the precharged output DUTY_HB to reduce the potential thereof.

While the clock signals LCLKOET/B are at low level, the differential input MOS transistors 62 and 63 are kept OFF to hold the potentials of the output DUTY_HB and DUTY_LB, respectively. Therefore, the potentials of the outputs DUTY_HB and DUTY_LB are decreased in proportion to the period for which the clock is at high level. For example, after inputting two cycles of clock, the potentials of the outputs DUTY_HB and DUTY_LB are compared by the comparator 73 to determine a difference of the potentials. A determination signal LDCT is then output based on the determination result.

When the clock duties are equal, the potentials of the outputs DUTY_HB and DUTY_LB are also equal to each other. Consideration is given to the case where there is duty deviation and the duty is 40% (40% high level period in a cycle period), for example. In this case, the ON period of the MOS transistor 63 on the inverted clock LCLKOEB side becomes longer and the potential of the output DUTY_HB is decreased more. In the case of the duty of 60%, in contrast, the ON period of the MOS transistor 62 on the clock LCLKOET side becomes longer and the potential of the output DUTY_LB is decreased more. The duty deviation is detected by extracting the precharged potential in a period proportional to the duty.

However, such conventional duty detection methods have problems as described below.

Firstly, the speed of extracting the electric charge at the start of detection is different between the clock LCLKOET and the inverted clock LCLKOEB. The conventional duty detection of the clocks LCLKOET and LCLKOEB is performed for a period of several consecutive cycles (two cycles in FIG. 2) with a time difference of a half cycle. Accordingly, the drain voltage (BIASND) of the current source MOS transistor is at the ground level at the start of the detection of the “H” period of the clock LCLKOET. However, the drain voltage BIASND is at an intermediate potential when the detection of the “H” period of the inverted clock LCLKOEB is started, because the detection of the clock LCLKOET has been already performed.

As described above, the potential at the common node BIASND at the start of detection is different between the clock LCLKOET and the inverted clock LCLKOEB, the potential of the clock LCLKOET being the ground potential and the potential of the inverted clock LCLKOEB being an intermediate potential. Consequently, the speed of extracting electric charge at the start of detection is different between the clock LCLKOET and the inverted clock LCLKOEB. This means that the duty deviation cannot be reflected accurately in the difference in potential. This disadvantage becomes more notable as the power source voltage is decreased, and thus poses a problem when the voltage is low and the operation speed is increased.

Secondly, the duty cannot be detected in two consecutive cycles. In a divide-by-two DLL circuit, for example, an internal clock is frequency-divided by two and then multiplied to be clocks LCLKOET/B. The delay amounts are internally adjusted separately between the odd-numbered cycles and the even-numbered cycles of the regenerated clocks LCLKOET/B. This means that, as shown in FIG. 3, a Rise_Even edge, a Rise_Odd edge, a Fall_Even edge, and a Fall_Odd edge are independent from each other within the clocks. Accordingly, the clock may have different duties between odd numbered cycles and even numbered cycles. When the duty is detected in two consecutive cycles, the duty will be 50% on average if the duty is 60% in the odd numbered cycle and 40% in the even numbered cycle. Therefore, the duty deviation cannot be detected. In this manner, according to the conventional techniques, the duty cannot be detected in two consecutive cycles in a divide-by-two DLL circuit.

These conventional duty detection circuits are described in Japanese Laid-Open Patent Publication No. 2002-190196 (Patent Publication 1) and Japanese Laid-Open Patent Publication No. 2002-042469 (Patent Publication 2). The conventional DLL circuit is described in Japanese Laid-Open Patent Publication No. 2003-188694 (Patent Publication 3), for example. However, none of these patent publications mention the problems above or suggest measures to solve the problems.

### SUMMARY OF THE INVENTION

As described above, the conventional duty detection circuit has a problem that the speed of extracting electric charge at the start of detection is different between the clock LCLKOET and the inverted clock LCLKOEB, which makes it impossible to accurately reflect the duty deviation as difference in potential. In the duty detection circuit of a divided-by-two DLL circuit in which the clock is frequency divided and multiplied, the clock duty in odd-numbered cycles is different from that in even-numbered cycles, which makes it impossible to detect the duty in consecutive cycles.

In view of the problems as mentioned above, it is an object of the present invention to provide a duty detection circuit capable of accurate detection of duty deviation, and a DLL circuit and semiconductor device having such duty detection circuit.

According to the present invention, duty detection is performed once every two cycles. The detection of clock “H” level is started by the input of the clock, whereas the detection of clock “L” level is started after a delay for a half cycle from the input of the clock. The potential at the common contact is reset to an initial set value during the delayed time. The speed of extracting electric charge is made equal between the odd-numbered and even-numbered cycles by resetting the potential at the common contact to the initial set value, which enables accurate duty detection. A frequency dividing DLL circuit is provided with duty detection circuits separately for the even-numbered and odd-numbered cycles so that the duty is detected separately in the even-numbered and odd-numbered cycles. In this manner, the present invention is able to provide a DLL circuit and semiconductor device capable of accurate timing adjustment to the clock.

In order to achieve the object described above, the present invention basically employs the techniques as described below. It is to be understood that many modifications and variations of the present invention are possible without departing from the scope of the invention.

A duty detection circuit according to the present invention is characterized in that one logic level period per cycle is measured from the time point when the logic level is input, while the other logic level period is measured after a delay for a specified delay time from the time point when the other logic level is input.

In the duty detection circuit according to the present invention, the potential of a common contact is reset to an initial set value during the specified delay time.

In the duty detection circuit according to the present invention, the specified delay time is a half of the cycle time.

In the duty detection circuit according to the present invention, the duty is measured once every two consecutive cycles.

The duty detection circuit according to the present invention includes a current source circuit connected between a common contact and a ground potential, a first input transistor connected to the common contact and a first output, a second input transistor connected to the common contact and a second output, and a delay circuit. The gate of the first input transistor receives an input of a signal that is activated during the one logic level, and the gate of the second input transistor receives a signal that is activated during the other logic level and is input thereto after being delayed by the delay circuit.

A DLL circuit according to the present invention includes a duty detection circuit described above as a first duty detection circuit for detecting the duty of an even-numbered cycle, and another duty detection circuit described above as a second duty detection circuit for detecting the duty of an odd-numbered cycle.

The DLL circuit according to the present invention further includes a first duty correction circuit for correcting the duty of the even-numbered cycle according to an output from the first duty detection circuit, and a second duty correction circuit for correcting the duty of the odd-numbered cycle according to an output from the second duty detection circuit.

In the DLL circuit according to the present invention, the first and second duty correction circuits adjust the timing at the falling edge of the even-numbered and odd-numbered cycles, respectively.

A semiconductor device according to the present invention includes a DLL circuit as described in any one of the paragraphs above.

The present invention provides advantageous effects as described below.

(1) The potential of the common contact at the start of each duty detection is reset to the initial set value. When the operating voltage is decreased, the source-drain voltage (node voltage BIASND) of the current source MOS transistor of the detection circuit affects the detection accuracy. Therefore, the detection accuracy can be improved by initializing the detection circuit at the start of every detection.

(2) Separate duty detection circuits are provided for odd-numbered and even-numbered cycles, respectively. In a DLL circuit designed to frequency-divide an external clock by two, adjust them and then synthesize the divided clocks again, the odd-numbered cycles and even-numbered cycles have separate delay amounts and are controlled separately. This makes it impossible to perform duty detection in consecutive cycles. According to the present invention in which detection is performed once every two cycles, two separate detection circuits (one for even-numbered cycles and one for odd-numbered cycles) are used, and thus the present invention can be advantageously applied to a divide-by-two DLL circuit.

### BRIEF DESCRIPTION OF THE DRAWINGS

FIG. 1 is a circuit diagram showing a duty detection circuit according to a related prior art;

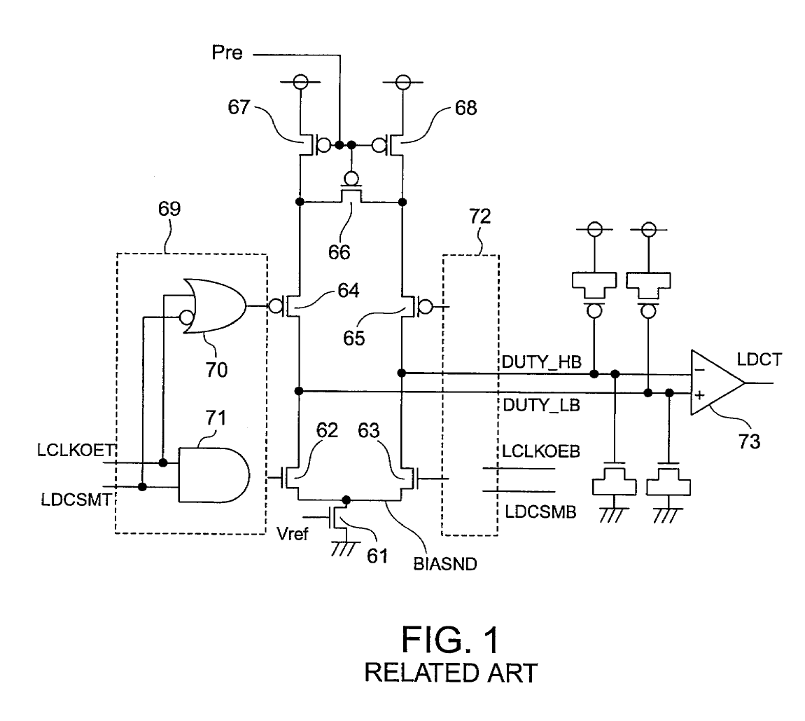

FIG. 2 is a timing chart of the duty detection circuit according to the related prior art;

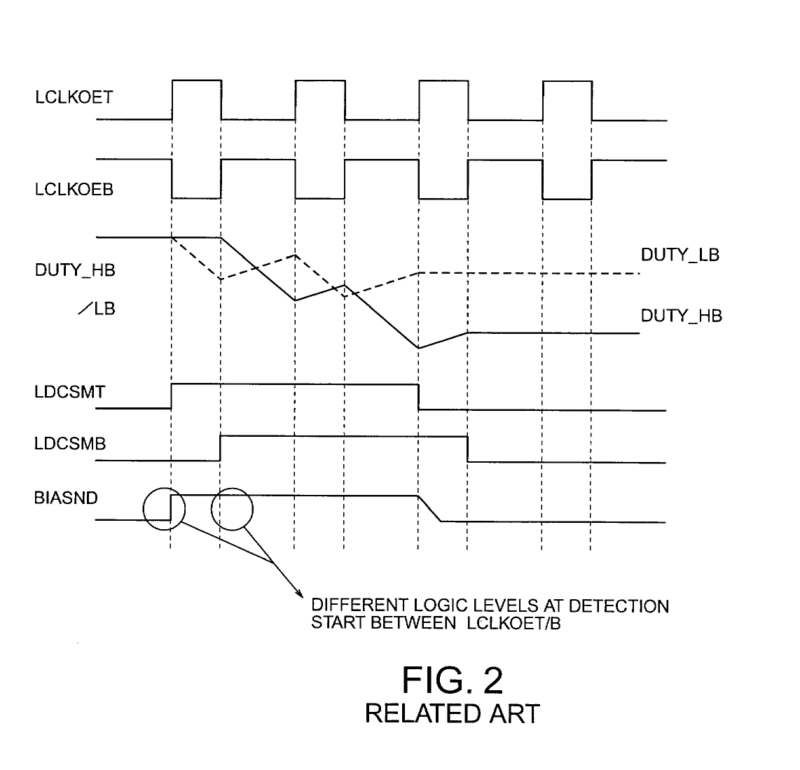

FIG. 3 is an explanatory diagram for illustrating timings at various edges when a clock is multiplied;

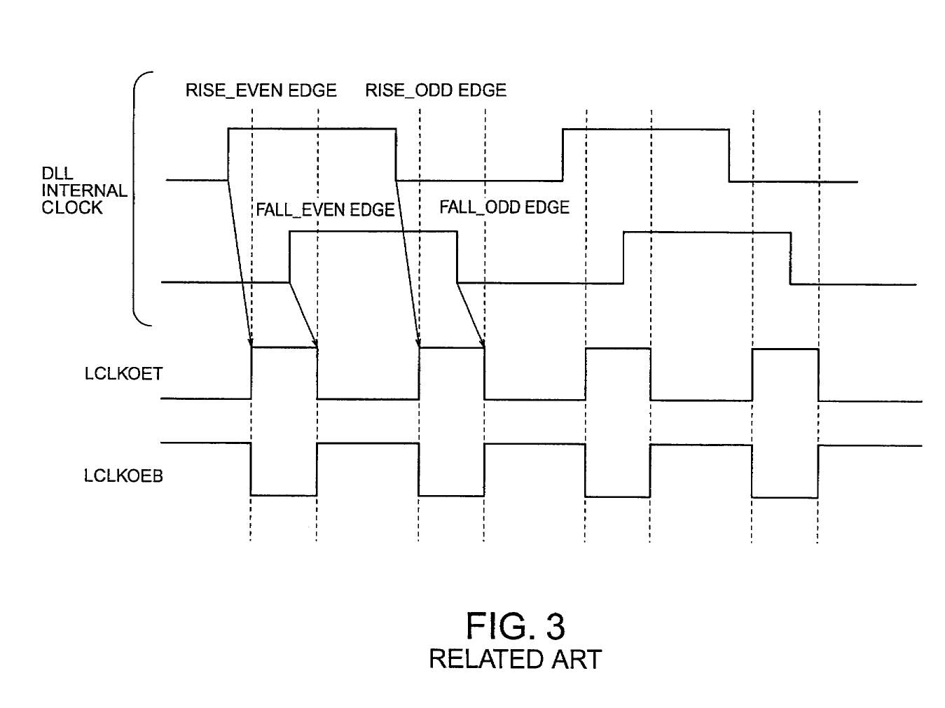

FIG. 4 is a circuit diagram showing a duty detection circuit according to a first embodiment of the present invention;

FIG. 5 is a timing chart of the duty detection circuit of FIG. 4;

FIG. 6 is a block diagram showing a DLL circuit according to a second embodiment of the present invention;

FIG. 7 is a timing chart of the DLL circuit of FIG. 6; and

FIG. 8 is a diagram illustrating the relationship between a number of cycles and duty correction of the DLL circuit of FIG. 6.

### DESCRIPTION OF THE PREFERRED EMBODIMENTS

Preferred embodiments of the present invention will be described with reference to the drawings.

### First Embodiment

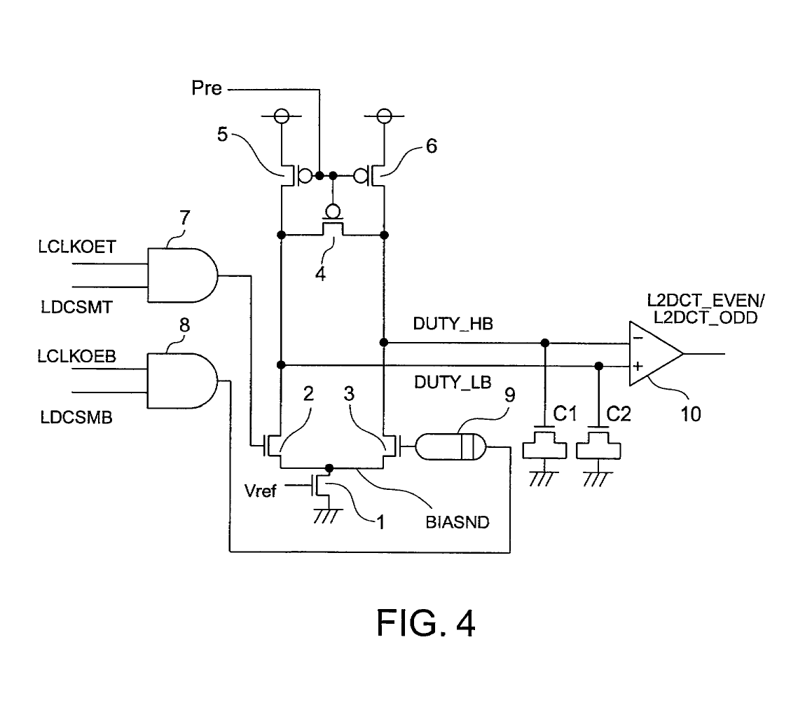

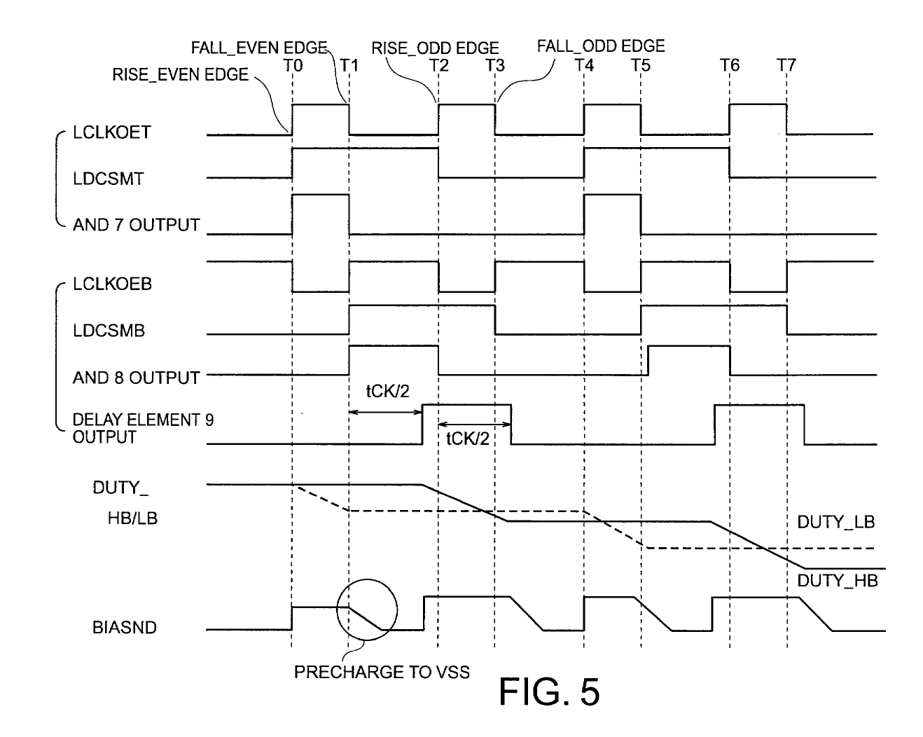

A first embodiment of the present invention will be described in detail with reference to FIGS. 4 and 5. The first embodiment relates to a duty detection circuit, and FIG. 4 is a circuit diagram showing a duty detection according to the first embodiment, FIG. 5 being a timing chart of the duty detection circuit.

FIG. 4 shows the duty detection circuit for detecting the duty of clocks according to the present invention.

Complementary clocks LCLKOET and LCLKOEB are used for example as clocks for controlling timing of output data of a DDR-SDRAM. The clocks are composed of even-numbered clocks synchronized with the rising edges of a basic clock, and odd-numbered clocks synchronized with the falling edges of the basic clock, and the even-numbered clocks and odd-numbered clocks have different duties. Description of the first embodiment will be made in terms of the duty detection of an even-numbered clock since configuration and operation are similar for both the even-numbered and odd-numbered cycles.

The duty detection circuit is of a differential amplifier type, and includes a current source MOS transistor 1, differential input MOS transistors 2 and 3, precharge MOS transistors 4, 5, and 6, input controlling AND circuits 7 and 8, a delay element 9, capacitors C1 and C2, and a comparator 10 for comparing outputs DUTY_HB and DUTY_LB from the differential amplifier.

The drain, source, and gate of the current source MOS transistor 1 are connected to a common contact BIASND, a ground potential, and a reference potential, respectively. The drain, source, and gate of the differential input MOS transistor 2 are connected to the output DUTY_LB, the common contact BIASND, and the output of the AND circuit 7, respectively. The drain, source, and gate of the differential input MOS transistor 3 are connected to the output DUTY_HB, the common contact BIASND, and the output of the delay element 9, respectively. The current drive capabilities of the differential input transistors 2 and 3 are set equal to each other.

The precharge MOS transistor 4 is connected between the outputs DUTY_HB and DUTY_LB, and the gate is connected to a precharge signal Pre. The drain, source, and gate of the precharge MOS transistor 5 are connected to the output DUTY_LB, a power source potential, and the precharge signal Pre, respectively. The drain, source, and gate of the precharge MOS transistor 6 are connected to the output DUTY_HB, the power source potential, and the precharge signal Pre, respectively.

The AND circuit 7 receives a clock signal LCLKOET and a clock detection start signal LDCSMT, and an output of the AND circuit 7 is input to the gate of the differential input MOS transistor 2. The AND circuit 8 receives an inverted clock signal LCLKOEB and an inverted clock detection start signal LDCSMB, and an output of the AND circuit 8 is input to the delay element 9. The delay element 9 delays the signal from the AND circuit 8, and outputs the delayed signal to the gate of the differential input MOS transistor 3. The capacitors C1 and C2 are connected to the outputs DUTY_HB and DUTY_LB, respectively, to accumulate output electric charge. Capacities of the capacitors C1 and C2 are set equal to each other in this example. The comparator 10 receives the output DUTY_HB and the output DUTY_LB, determines which of the outputs has a higher potential, and outputs a determination output L2DCT_Even (L2DCT_Odd in the case of odd-numbered cycles).

Operation of the duty detection circuit shown in FIG. 4 will be described with reference to the timing chart of FIG. 5.

In FIG. 5, the duty is assumed to be about 40% (the ratio of high level period per cycle period is 40%). Prior to duty detection, the precharge signal Pre is activated (herein, the precharge signal is turned to low level). The precharge MOS transistors 4, 5, and 6 are turned ON, and the output DUTY_HB and the output DUTY_LB are charged to the level of the power source potential. Both the differential input MOS transistors 2 and 3 are OFF while the current source MOS transistor 1 is ON, and the common contact BIASND is at the ground potential.

At time T0, an even-numbered clock LCLKOET rises to “H” level, and the detection start signal LDCSMT is activated to a logic “H” level. The time T0 is a Rise_Even edge, at which duty detection of “H” level period in an even-numbered clock cycle is started. Since the both inputs to the AND circuit 7 are “H” level, the AND circuit 7 outputs an “H” level signal. The differential input MOS transistor 2 is turned ON, and the potential thereof is reduced (the potential of the output DUTY_LB is indicated by the broken line in FIG. 5) by extracting the electric charge of the output DUTY_LB. Accordingly, the potential at the common contact BIASND is raised. At this time, the inverted clock detection start signal LDCSMB is inactive, the differential input MOS transistor 3 is OFF, and the potential of the output DUTY_HB is held stable (the potential of the output DUTY_HB is indicated by the solid line in FIG. 5).

At time T1, the clock LCLKOET drops to “L” level. The time T1 is a Fall_Even edge, at which the duty detection of “H” level period in the even-numbered clock cycle is ended and duty detection of “L” level period in the even-numbered clock cycle is to be started. The differential input MOS transistor 2 is turned OFF and no electric charge is extracted from the output DUTY_LB. The inverted clock detection start signal LDCSMB is activated, the inverted clock LCLKOEB becomes “H” level, and the output of the AND circuit 8 becomes “H” level.

However, since the output of the AND circuit 8 is delayed by a half cycle of the clock (tCK/2) by the delay element 9, the duty detection of “L” level period in the even-numbered clock cycle is not started. The output of the AND circuit 8 is delayed by the delay element 9, and the input to the differential input MOS transistor 3 remains “L” level. Accordingly, the differential input MOS transistor 3 is OFF and the potential of the output DUTY_HB is held unchanged. The differential input MOS transistors 2 and 3 are both OFF and thus no electric charge is extracted. Consequently, the common contact BIASND is reset to the ground potential that is the initial set value. In this manner, the output of the AND circuit 8 is delayed by the delay element 9, and the common contact BIASND is reset to the initial set value.

At the time point when a half cycle has elapsed from the time T1, the input to the differential input MOS transistor 3 that has been delayed changes to “H” level. Accordingly, the differential input MOS transistor 3 is turned ON, and the electric charge of the output DUTY_HB is extracted to decrease the potential thereof. When the electric charge is extracted, the common contact BIASND will rise from the ground potential in the same manner as when the clock LCLKOET is input. The electric charge extraction at the clock LCLKOET and the inverted clock LCLKOEB is both started from the ground potential that is the initial set value of the common contact BIASND. Therefore, the speed of extracting the electric charge of the clock LCLKOET is equal to that of the inverted clock LCLKOEB.

At time T2, the clock LCLKOET becomes “H” level in an odd-numbered cycle, while the inverted clock LCLKOEB becomes “L” level. The time T2 is a Rise_Odd edge, at which the duty detection of “L” level period in the even numbered clock cycle is ended and duty detection of “H” level period in the odd-number clock cycle is to be started. However, the detection start signal LDCSMT is inactivated to a logic “L” level, and thus the duty detection of “H” level period in the odd-number clock cycle is not started. The output of the AND circuit 7 remains “L” level, and no electric charge extraction is performed on the clock LCLKOET side.

On the other hand, the electric charge extraction on the inverted clock LCLKOEB side is continuously performed due to the output of the AND circuit 8 that is delayed by the delay element 9. Accordingly, at time T2, duty detection in the odd-numbered cycle is not performed, whereas duty detection of “L” level period in the even-numbered cycle is performed. Although an odd numbered cycle clock is input at time T2, duty detection in the odd-numbered cycle is not performed but duty detection of the even-numbered cycle is performed. At time T3, the clock LCLKOET becomes “L” level in an odd-numbered cycle, while the inverted clock LCLKOEB becomes “H” level. The time T3 is a Fall_Odd edge, at which the duty detection of “H” level in the odd-numbered clock cycle is ended and duty detection of “L” level is to be started. However, the clock detection start signal LDCSMT is made “L” level while the inverted clock detection start signal LDCSMB is also made “L” level, and thus the duty in the odd-numbered clock cycle is not detected.

The inverted clock detection start signal LDCSMB is inactivated to a logic “L” level, whereby the output of the AND circuit 8 is changed to “L” level. However, since the output is delayed by a half cycle by the delay element 9, the gate input to the differential input MOS transistor 3 remains “H” level, and hence the electric charge extraction on the inverted clock LCLKOEB side is continuously performed. The “L” level output of the AND circuit 8 is input from the delay element 9 at the time point when a half cycle has elapsed from the time T2, whereby the differential input MOS transistor 3 is turned OFF and the electric charge extraction is ended. The common contact BIASND also again assumes the ground potential that is the initial set value.

At time T4, the clock LCLKOET becomes “H” level in an even-numbered cycle, while the inverted clock LCLKOEB becomes “L” level. Operation in the even-numbered cycle is the same as that at the time T0, and the potential of the output DUTY_LB is decreased further. At time T4, T6, T7 and onwards, similar operation to that at the time T1, T2, and T3 is repeated whereby the potential of the output DUTY_LB and the output DUTY_HB is decreased according to the duty. These outputs are compared by the comparator 10, which outputs a determination signal. Upon receiving the determination signal, a duty correction circuit (not shown) corrects the duty to 50%.

The duty detection of the duty detection circuit according to the first embodiment is performed once every two cycles. Therefore, separate duty detection circuits are provided for the even-numbered clock cycles and odd-numbered clock cycles, respectively. Duty detection for one of the logic levels (“H” level in this example) of the clock LCLKOET in an even- or odd-numbered cycle is performed at the time point when the clock is input. Duty detection for the other logic level, “H” level of the inverted clock LCLKOEB (“L” level of the clock LCLKOET) is performed after a delay of a half cycle (tCK/2) from the time at which the inverted clock is input.

This delay causes the duty detection for the inverted clock LCLKOEB to be performed involving the subsequent odd- or even-numbered cycle. The duty detection for the inverted clock LCLKOEB is delayed, and the common contact BIASND is reset to the initial set value during this delay period. The returning of the common contact BIASND to the initial set value makes it possible to equalize the speeds of extracting electric charge at the time of starting detection of the clock levels between the clock LCLKOET and the inverted clock LCLKOEB. As a result, the accuracy of the duty detection can be improved.

### Second Embodiment

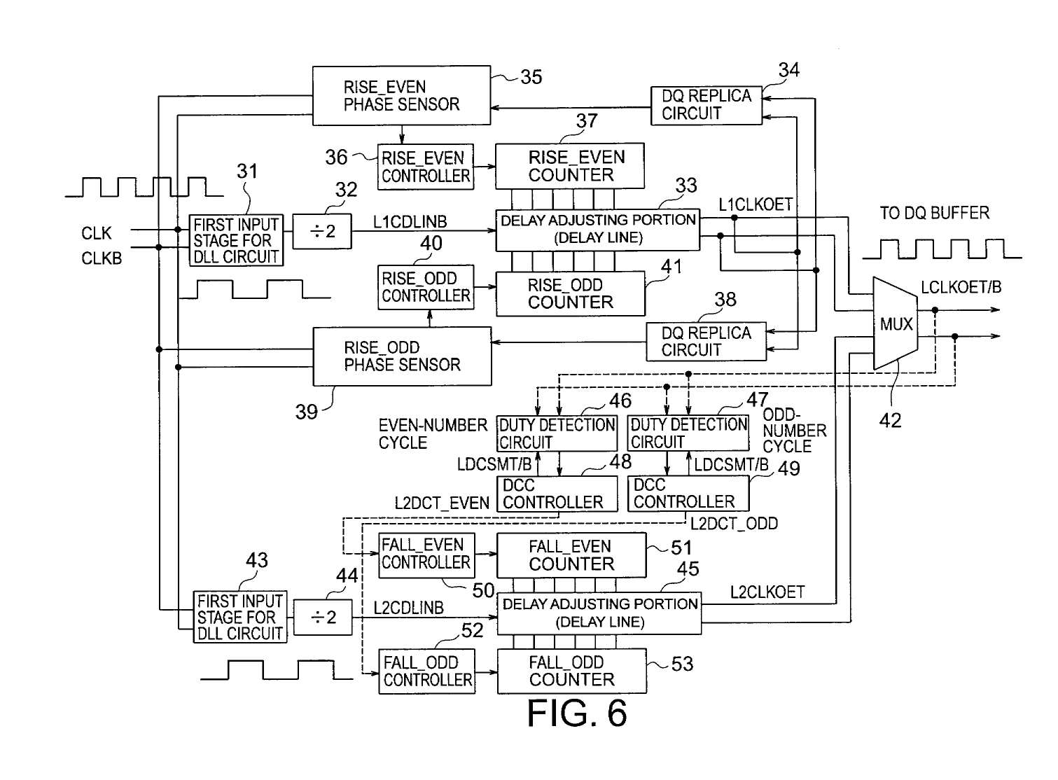

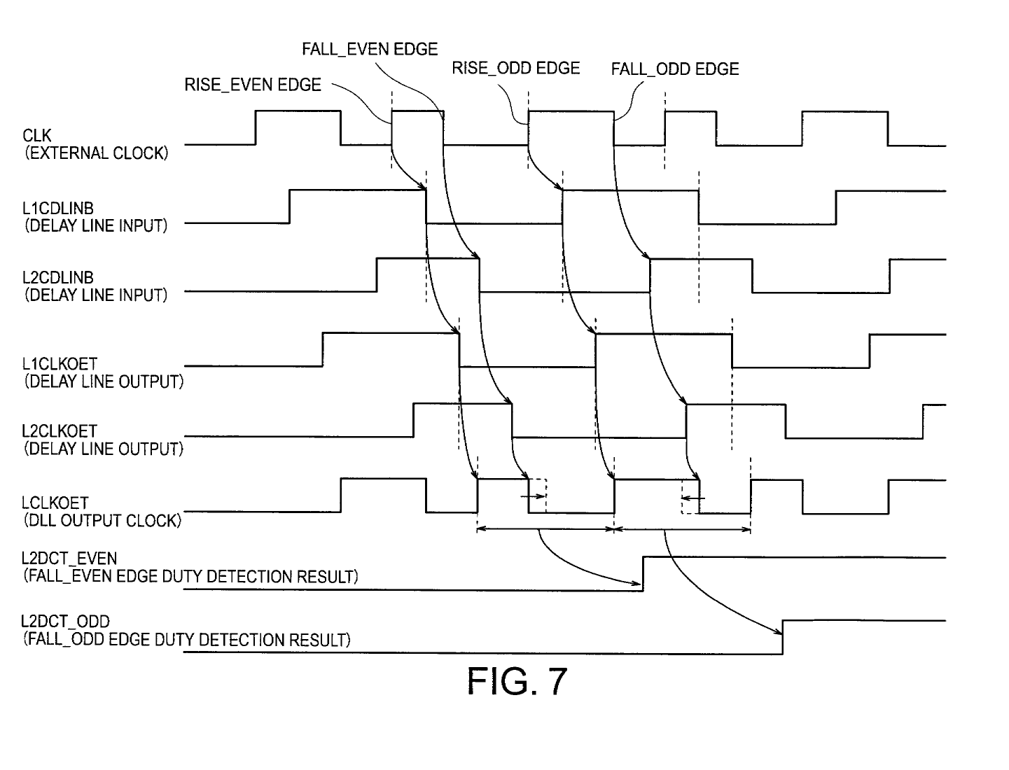

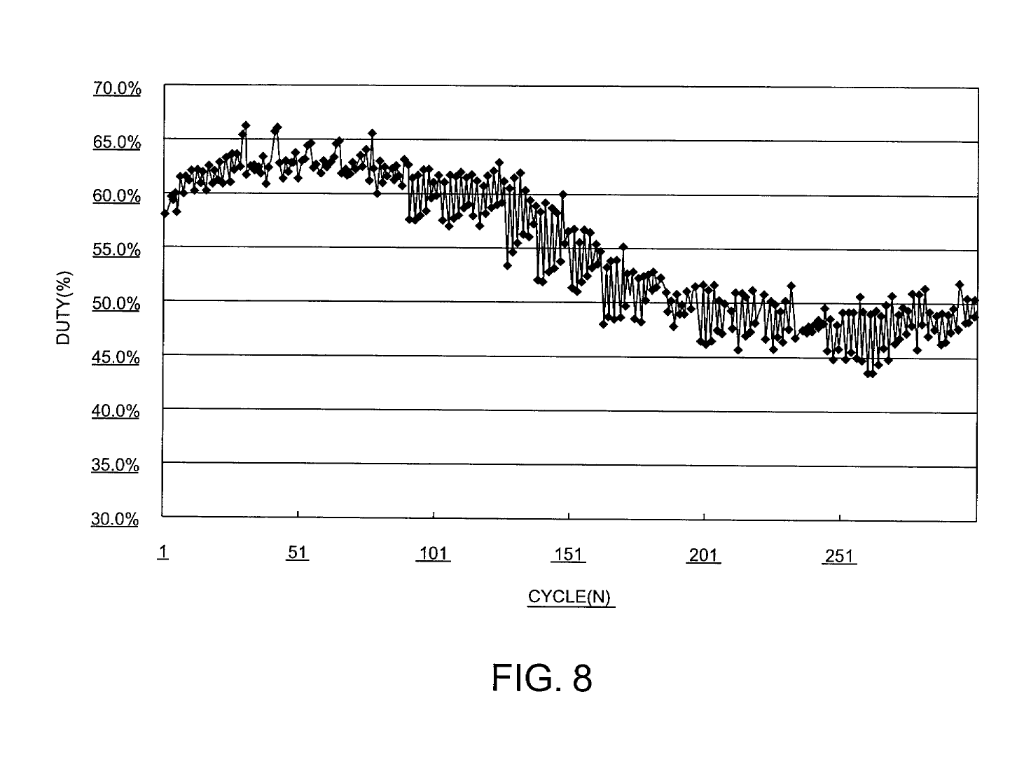

A second embodiment of the present invention will be described in detail with reference to FIGS. 6 to 8. The second embodiment is an embodiment in which the duty detection circuit of the first embodiment is applied to a DLL circuit. FIG. 6 is a block diagram showing a DLL circuit, and FIG. 7 is a timing chart thereof. FIG. 8 shows the results of duty correction on clock cycles.

FIG. 6 is a block diagram showing a DLL circuit to which the duty detection circuit of the first embodiment is applied. This DLL circuit is used as a semiconductor device in a DDR3-SDRAM, for example. An input clock CLK is input to the DLL circuit via a first input stage 31 for the DLL circuit. The clock input from the first input stage 31 for the DLL circuit is frequency-divided by a frequency divide circuit 32 using a rising edge and becomes a frequency-divided clock L1CDLINB. Similarly, a clock input via a first input stage 43 for the DLL circuit is frequency-divided by a frequency divide circuit 44 using a falling edge (rising edge of the inverted clock CLKB) and becomes a frequency-divided clock L2CDLINB. These frequency-divided internal clocks L1CDLINB and L2CDLINB are input to respective delay adjustment portions (delay lines) 33 and 45.

The frequency-divided internal clock L1CLDINB becomes clocks L1CLKOET and L1CLKOEB after passing through the delay line 33. The clocks L1CLKOET and L1CLKOEB are input to DQ replica circuits 34 and 38 which operate in a similar manner to a DQ buffer for outputting memory data. Outputs from the DQ replica circuits 34 and 38 are phase-compared with the input clock CLK by phase sensing circuits 35 and 39, respectively. The results of the phase comparison are fed back to the delay line and the delay amount of the delay line is adjusted such that the outputs of the DQ replica circuits are synchronized with the rising of the clock.

The phase sensing circuit 35 senses the phase of a Rise_Even edge, and the sensing result is input to a Rise_Even counter 37 via a Rise_Even controller 36. The Rise_Even counter 37 adjusts the phase of the falling edge of the frequency-divided clock L1CDLINB. The phase sensing circuit 39 senses the phase of a Rise_Odd edge, and the sensing result is input to a Rise_Odd counter 41 via a Rise_Odd controller 40. The Rise_Odd counter 41 adjusts the phase of the rising edge of the frequency-divided clock L1CDLINB. Consequently, the phases of both the rising and falling edges of the frequency-divided clock are adjusted.

On the other hand, the delay amount of the delay line to which the frequency-divided clock L2CDLINB is input is adjusted such that the duty of the output data from the DQ buffer is 50%. The frequency-divided internal clock L2CDLINB is input to the delay adjustment portion (delay line) 45 and output as a delay-adjusted clock L2CLKOET A multiplexer 42 receives the clock L1CLKOET from the delay line 33 and the clock L2CLKOET from the delay line 45 and synthesizes the clocks. The duties of DQ buffer clocks (LCLKOET/B) having the same frequency as the clock CLK are monitored by respective duty detection circuits, and monitoring results are sent to the delay line 45 for L2CDLINB to adjust the delay amount.

In this manner, the rising edges of the clocks LCLKOET/B having the same frequency as the clock CLK are adjusted by the delay line 33, while the falling edges are adjusted by the delay line 45. The adjusted clocks LCKOET/B are sent also to a DQ buffer, so that the timing of the data output from the DQ buffer is synchronized with the clock.

The description will be made with respect to duty detection and duty correction.

In FIG. 6, two duty detection circuits according to the first embodiment are provided as a duty detection circuit 46 for even-numbered cycles and a duty detection circuit 47 for odd-numbered cycles. The even-numbered cycle duty detection circuit 46 receives clocks LCLKOET/B and detection start signals LDCSMT/B from a duty correction controller 48 and detects the duty in an even-numbered cycle. The detection result is output as a determination signal L2DCT_Even to a Fall_Even counter 51 via a Fall_Even controller 50. The Fall_Even counter 51 adjusts the timing of the Fall_Even edge of the delay line 45. Accordingly, the “H” period and the “L” period in the even-numbered cycle of the clocks LCLKOET/B are equally adjusted to the duty of 50%.

Similarly, the odd-numbered cycle duty detection circuit 47 receives clocks LCLKOET/B and detection start signals LDCSMT/B from a duty correction controller 49 and detects the duty in an odd-numbered cycle. The detection result is output as a determination signal L2DCT_Odd to a Fall_Odd counter 53 via a Fall_Odd controller 52. The Fall_Odd counter 53 adjusts the timing of the Fall_Odd edge of the delay line 45. Accordingly, the “H” period and the “L” period of the odd-numbered cycle of the clocks LCLKOET/B are equally adjusted to the duty of 50%. Here, the Fall_Even controller 50 and the Fall_Even counter 51 may be collectively called a first duty correction circuit while the Fall_Odd controller 52 and the Fall_Odd counter 53 may be collectively called a second duty correction circuit.

The description will now be made with reference to the timing chart of FIG. 7.

The rising timing in an even-numbered cycle of the clock LCLKOET is determined based on the falling edges of L1CDLINB and L1CLKOET The falling timing is determined based on the falling edges of L2CDLINB and L2CLKOET The falling timing is further adjusted based on the determination result of the duty of the Fall_Even edge and is adjusted to the duty of 50%. Similarly, the rising timing in an odd-numbered cycle of the clock LCLKOET is determined based on the rising edges of L1CDLINB and L1CLKOET. The falling timing is determined based on the rising edges of L2CDLINB and L2CLKOET The falling timing is adjusted based on the determination result of the duty of the Fall_Odd edge and corrected to the duty of 50%.

As described above, the rising and falling edges of the even- and odd-numbered cycles independently have individual delay amounts, and thus two separate duty detection circuits are required. Each duty detection circuit has only to operate every two cycles, and therefore is able to use one cycle period for duty detection and use another cycle period for precharging the circuit while the other duty detection is carried out.

FIG. 8 is a chart illustrating the relationship between the duty and the number of cycles.

It can be seen from the chart that the duty is progressively corrected to 50% as the cycle is repeated.

The DLL circuit according to the second embodiment adjusts the rising timings of the even- and odd-numbered cycles. The DLL circuit further has duty detection circuits and correction circuits for even- and odd-numbered cycles to adjust the falling timings of the even- and odd-numbered cycles. Thus, the DLL circuit is not only able to perform the rising timing adjustment of the clocks LCLKOET/B but also to detect the duties to adjust the falling timings of the clocks LCLKOET/B. The potential of the common contact at the start of the duty detection is set to the initial set value to equalize the capability of extracting electric charge, whereby it is made possible to accurately detect the “H” period and the “L” period of the clock. The correct detection of the duty provides an advantageous effect of improving the timing adjustment accuracy. As a result, the present invention is able to provide a DLL circuit having improved timing adjustment accuracy and hence a semiconductor device having such DLL circuit and operable at high speed.

It should be understand that the foregoing detailed description relates to only preferred embodiments of the present invention, and the present invention is not limited thereto but may be otherwise variously embodied within the scope of the invention. Obviously such modifications and variations are intended to be included in the scope of the present invention.

For example, even if the frequency dividing number is increased to four or eight, the duty detection is possible by arranging the same number of detection circuits as the frequency dividing number. Further, even if the frequency is not divided, the effect of the drain-source voltage of the current source MOS transistor on the duty detection accuracy can be reduced and the duty detection accuracy can be improved by decreasing the power source voltage. Although the duty is 50% in the embodiments described above, the duty may be set to any desired ratio by changing the ratio of capacity values of the capacitors C1 and C2, or changing the current drive capability of the two input MOS transistors.

What is claimed is:

1. A duty detection circuit wherein one logic level period per cycle is measured from the time point when the logic level is input, while the other logic level period is measured after being delayed for a specified delay time from the time point when the other logic level is input.

2. The duty detection circuit according to claim 1, wherein the potential of a common contact is reset to an initial set value during the specified delay time.

3. The duty detection circuit according to claim 1, wherein the specified delay time is a half of the cycle time.

4. The duty detection circuit according to claim 3, wherein the duty is measured once every two consecutive cycles.

5. The duty detection circuit according to claim 1, comprising a current source circuit connected between a common contact and a ground potential, a first input transistor connected to the common contact and a first output, a second input transistor connected to the common contact and a second output, and a delay circuit,
wherein the gate of the first input transistor receives an input of a signal that is activated during the one logic level, and the gate of the second input transistor receives a signal that is activated during the other logic level and is input thereto after being delayed by the delay circuit.

6. A DLL circuit comprising a duty detection circuit according to claim 1 as a first duty detection circuit for detecting the duty of an even-numbered cycle, and another duty detection circuit according to claim 1 as a second duty detection circuit for detecting the duty of an odd-numbered cycle.

7. The DLL circuit according to claim 6, further comprising:
a first duty correction circuit for correcting the duty of the even-numbered cycle according to an output from the first duty detection circuit; and
a second duty correction circuit for correcting the duty of the odd-numbered cycle according to an output from the second duty detection circuit.

8. The DLL circuit according to claim 7, wherein the first and second duty correction circuits adjust the timing at the falling edge of the even-numbered and odd-numbered cycles, respectively.

9. A semiconductor device comprising a DLL circuit as claimed in claim 6.

10. A semiconductor device comprising a DLL circuit as claimed in claim 7.

11. A semiconductor device comprising a DLL circuit as claimed in claim 8.
